(19) United States
(12) Patent Application Publication
(10) Pub. No.: US 2010/0033915 A1
(43) Pub. Date: Feb. 11, 2010

(54) PORTABLE ELECTRONIC DEVICE

(75) Inventor: CHUN-HAO HSU, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: CHI MEI COMMUNICATION SYSTEMS, INC., Tu-Cheng City (TW)

(21) Appl. No.: 12/274,483

(22) Filed: Nov. 20, 2008

(30) Foreign Application Priority Data
Aug. 11, 2008 (CN) 200810303657.X

(51) Int. Cl. H05K 5/00

(52) U.S. Cl. 361/679.09

(57) ABSTRACT

A portable electronic device includes a housing, a circuit board, and a keyboard. The housing defines a receiving space. The circuit board is secured in the receiving space and includes a number of first latching portions. The keyboard includes a number of second latching portions corresponding to the first latching portions, the second latching portions are capable of latching with the first latching portions.

### TECHNICAL FIELD

The present invention relates to portable electronic devices and, particularly, to a portable electronic device to which a keyboard can be firmly fixed.

### DESCRIPTION OF THE RELATED ART

A typical portable electronic device includes a housing defining a receiving space, a circuit board received in the receiving space, and a keyboard used for inputting information to control the portable electronic device. The keyboard may have a number of latching protrusions extending from side surfaces thereof, and the housing includes a number of latching holes defined on side surface thereof corresponding to the latching protrusions. The keyboard is fixed to the housing by the engagement of the latching protrusions and holes. Because of the limitation of the thickness of the housing, the depth of the latching hole can be too small. Also, for the portable electronic device to have a good appearance, the latching protrusions can not extend far out of the housing through the latching holes. As a result, the keyboard usually cannot be fixed to the housing firmly. When the portable electronic device falls or suffers an impact, the keyboard can easily separate from the housing.

Therefore, there is room for improvement within the art.

### BRIEF DESCRIPTION OF THE DRAWINGS

Many aspects of the present portable electronic device can be better understood with references to the accompanying drawings. The components in the drawing are not necessarily drawn to scale, the emphasis instead being placed upon clearly illustrating the principles of the present portable electronic device.

FIG. 1 is a schematic, isometric view of a portable electronic device, which includes a circuit board, a keyboard, and a housing, according to a first exemplary embodiment.

FIG. 2 is a schematic, exploded view of the portable electronic device of FIG. 1.

FIG. 3 is an inversed schematic and isometric view of the keyboard of the portable electronic device of FIG. 1.

FIG. 4 is a schematic, assembled view of the circuit board and the keyboard of the portable electronic device of FIG. 1.

FIG. 5 is a schematic, exploded view of a portable electronic device according to a second exemplary embodiment.

FIG. 6 is an inversed schematic and isometric view of a keyboard of the portable electronic device of FIG. 5.

### DETAILED DESCRIPTION OF THE EMBODIMENTS

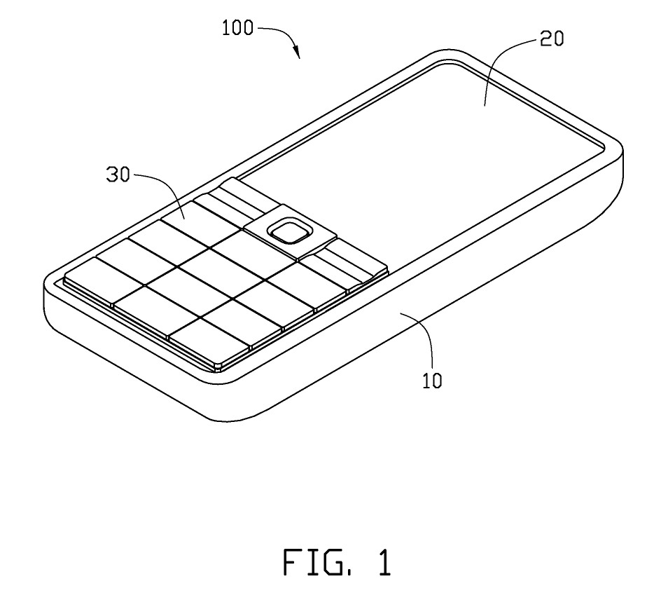

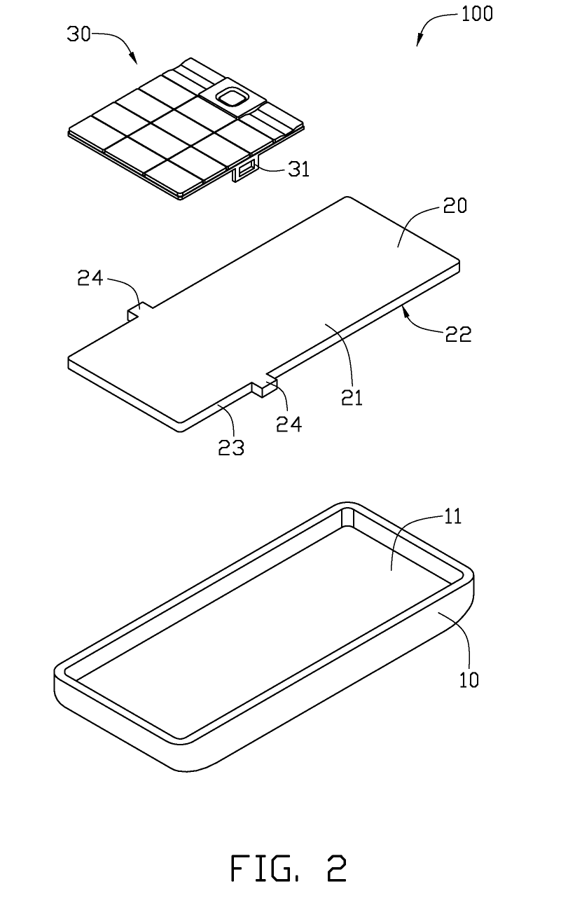

Referring to FIGS. 1 and 2, a portable electronic device 100 according to a first exemplary embodiment is shown. The portable electronic device 100 includes a housing 10, a circuit board 20, and a keyboard 30.

The housing 10 defines a receiving space 11 for receiving the circuit board 20.

The circuit board 20 is secured to the housing 10 by fasteners (not shown), such as screws, bolts, etc. The circuit board 20 includes a first surface 21 substantially parallel to the keyboard 30, an opposite second surface 22, and side surfaces 23. Two first latching portions 24 are respectively formed on the two opposite long-side surfaces 23. The first latching portions 24 can be integrally formed with the circuit board 20. In the present embodiment, the first latching portions 24 are protrusions respectively extending out from the opposite long-side surfaces 23.

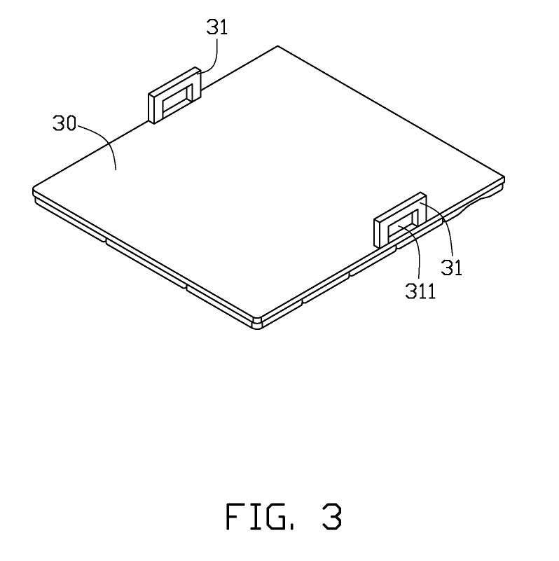

Referring to FIGS. 2 to 3, the keyboard 30 covers a portion of the first surface 21 of the circuit board 20. The keyboard 30 includes two second latching portions 31 corresponding to the first latching portions 24. In the present embodiment, each of the second latching portions 31 extends towards the circuit board 20 and has a hole 311 defined therein for receiving the first latching portion 24. To easily assemble the keyboard 30 and the circuit board 20, the second latching portion 31 can be made of elastic material, such as elastic plastic, elastic metal and so on. The second latching portion 31 can be integrally formed with the keyboard 30.

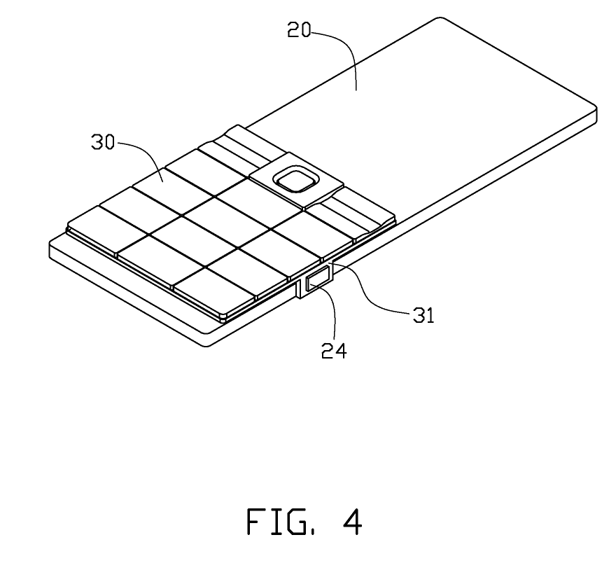

Further referring to FIG. 4, to assemble the portable electronic device 100, the circuit board 20 and the keyboard 30 are firstly assembled together by the first latching portions 24 latching with the second latching portions 31, and then, secure the circuit board 20 into the receiving space 11 of the housing 10.

In the portable electronic device 100, because the keyboard 30 is secured to the circuit board 20, the thickness of the housing 10 of the portable electronic device 100 does not affect the securing of the keyboard 30. Furthermore, because the housing 10 of the portable electronic device 100 need not define a hole to secure the keyboard 30, the portable electronic device 100 can have a nicer appearance.

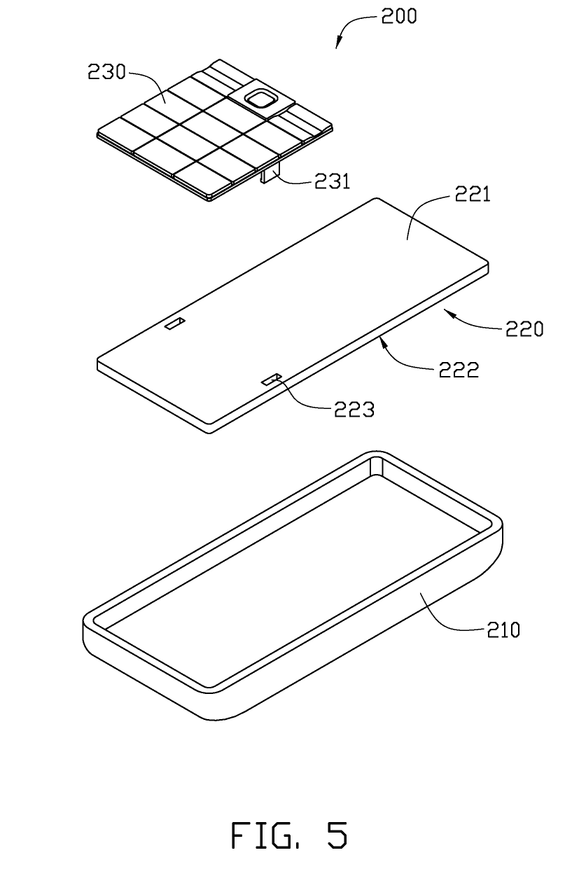

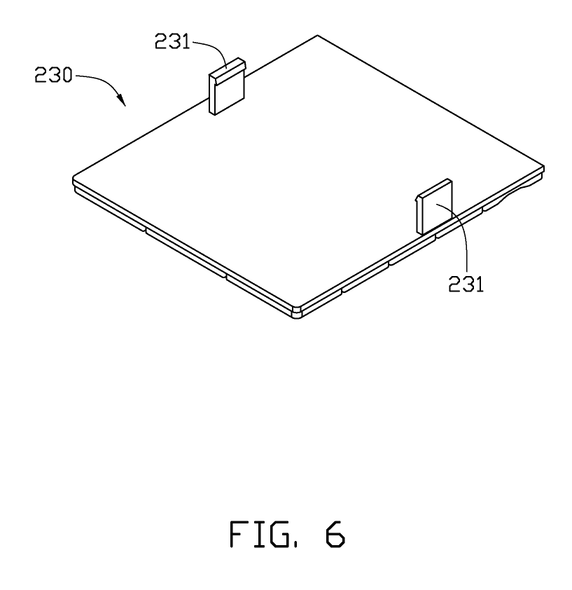

Referring to FIGS. 5 to 6, a portable electronic device 200 according to a second exemplary embodiment is shown. The portable electronic device 200 includes a housing 210, a circuit board 220, and a keyboard 230. The circuit board 220 includes a first surface 221, an opposite second surface 222, and a number of first latching portions 223. The keyboard 230 includes a number of second latching portions 231 corresponding to the first latching portions. The portable electronic device 200 is similar to the portable electronic device 100 of the first exemplary embodiment. The difference between the portable electronic device 200 and the portable electronic device 100 is that, in the portable electronic device 200, the first latching portion 223 are latching holes running through the first surface 221 and the second surface 222, and the second latching portion 231 are latching hooks extending downwardly towards the circuit board 220 from the keyboard 230. The latching hook can be inserted into the latching hole and hook the second surface 222 to securing the keyboard 230 on the circuit board 220.

While certain embodiments have been described and exemplified above, various other embodiments will be apparent to those skilled in the art from the foregoing disclosure. The present invention is not limited to the particular embodiments described and exemplified, and the embodiments are capable of considerable variation and modification without departure from the scope of the appended claims.

What is claimed is:

1. A portable electronic device comprising:
a housing defining a receiving space therein;
a circuit board secured in the receiving space, the circuit board comprising a plurality of first latching portions; and
a keyboard connected to the circuit board, the keyboard comprising a plurality of second latching portions corresponding to the first latching portions, the second latching portions capable of latching with the first latching portions.

2. The portable electronic device as claimed in claim 1, wherein the circuit board comprises a plurality of side surfaces, at least two of the first latching portions are protrusions extending from the side surfaces along a direction substantially parallel to the circuit board, at least two second latching portions correspond to two first latching portions and each protrusion defines a hole extending towards the circuit board.

3. The portable electronic device as claimed in claim 2, wherein the two first latching portions extend from opposite side surfaces of the circuit board.

4. The portable electronic device as claimed in claim 2, wherein the second latching portions are made of elastic material.

5. The portable electronic device as claimed in claim 4, wherein the elastic material is selected from the group consisting of elastic plastic and elastic metal.

6. The portable electronic device as claimed in claim 1, wherein the circuit board comprises a first surface substantially parallel to the keyboard and an opposite second surface, the first latching portions are latching holes running through the first surface and the second surface, and the second latching portions are latching hooks extending towards the circuit board from the keyboard.

7. The portable electronic device as claimed in claim 6, wherein the second latching portions are made of elastic material.

8. The portable electronic device as claimed in claim 7, wherein the elastic material is selected from the group consisting of elastic plastic and elastic metal.

9. The portable electronic device as claimed in claim 1, wherein the first latching portions are integrally formed with the circuit board.

10. The portable electronic device as claimed in claim 1, wherein the second latching portions are integrally formed with the keyboard.

11. A portable electronic device comprising:
a housing defining an opening;
a keyboard covering the opening and together with the housing to define a receiving space, the keyboard comprising a latching structure; and
a circuit board fixed in the receiving space and comprising a latching portion latching with the latching structure of the key board to fix the keyboard to the circuit board.

12. The portable electronic device as claimed in claim 11, wherein the circuit board comprises a plurality of side surfaces, the latching portion includes protrusions extending from the side surfaces along a direction substantially parallel to the circuit board, the latching structure corresponding to the latching portions comprises protrusions, each protrusion defining a hole extending towards the circuit board.

13. The portable electronic device as claimed in claim 12, wherein the latching portion comprises protrusions extending from opposite side surfaces of the circuit board.

14. The portable electronic device as claimed in claim 12, wherein the latching structure is made of elastic material.

15. The portable electronic device as claimed in claim 14, wherein the elastic material is selected from the group consisting of elastic plastic and elastic metal.

16. The portable electronic device as claimed in claim 11, wherein the latching portion is integrally formed with the circuit board.

17. The portable electronic device as claimed in claim 11, wherein the latching structure is integrally formed with the keyboard.
